(19) United States
(12) Patent Application Publication
(10) Pub. No.: US 2011/0188974 A1
(43) Pub. Date: Aug. 4, 2011

(54) WORK-PIECE TRANSFER SYSTEMS AND METHODS

(75) Inventor: Paul Diamond, North Billerica, MA (US)

(73) Assignee: ULVAC TECHNOLOGIES, INC., Chigasaki-shi, Kanagawa (JP)

(21) Appl. No.: 12/997,676

(22) PCT Filed: Jun. 30, 2009
(86) PCT No.: PCT/US09/49189

§ 371 Date: Apr. 19, 2011

Related U.S. Application Data
(60) Provisional application No. 61/080,943, filed on Jul. 15, 2008.

(51) Int. Cl. H01L 21/677; B25J 9/00

(52) U.S. Cl. 414/217; 414/222.07; 901/2

(57) ABSTRACT

A dual-robot transfer system including: a transfer module for transferring work-pieces into and out of a process module; a physical interface between the transfer module and a supply-and-accept system; a first robot located substantially in the transfer module for transferring work-pieces to and from the process module and a buffer station located in the transfer module, the first robot including a first top arm and a first bottom arm, the first top arm and first bottom arm substantially having a first range of motion; and a second robot located substantially in the transfer module for transferring work-pieces to and from the process module, the buffer station, and the physical interface, the second robot including a second top arm and a second bottom arm, the second top arm and second bottom arm substantially having a second range of motion which overlaps in part with the first range of motion.

### CROSS-REFERENCE TO RELATED APPLICATION

This application claims the benefit of U.S. Provisional Patent Application No. 61/080,943, filed Jul. 15, 2008, which is hereby incorporated by reference herein in its entirety.

### BACKGROUND

Semiconductor circuits can be fabricated on silicon wafers that undergo a variety of process steps during their manufacturing. During manufacture, the wafers are typically transported into and out of various specialized chambers, such as, for example, a process chamber. Many wafer transfer systems use either a selective compliant assembly robot arm (SCARA) or a bi-symmetric robot arm design to transfer wafers into and out of a process chamber. These robots move one arm into the process chamber at a time. For a single arm design, for example, a robot arm removes a processed wafer from the chamber, places it in a buffer station, gets the next unprocessed wafer, and places it in the process chamber. For a dual arm design, for example, a first arm picks the wafer from the process chamber, and then retracts the first arm and rotates it out of the way to make room for a second arm. The second arm then rotates into position, extends into the chamber, and drops off the next wafer for processing. These designs involve various steps that move arms into and out of the chamber and that move arms out of the way, each of these steps adds to the time it takes to transport wafers.

### SUMMARY

This disclosure relates to work-piece transfer systems, methods, and media. Some embodiments provide a dual-robot transfer system for use with a supply-and-accept system and a processing module, said dual-robot transfer system including: a transfer module for transferring work-pieces into and out of the process module; a physical interface between the transfer module and the supply-and-accept system which supplies unprocessed work-pieces to the transfer module and accepts processed work-pieces from the transfer module; a first robot located substantially in the transfer module for transferring work-pieces to and from the process module and a buffer station located in the transfer module, the first robot including a first top arm and a first bottom arm, the first top arm and first bottom arm substantially having a first range of motion; and a second robot located substantially in the transfer module for transferring work-pieces to and from the process module, the buffer station, and the physical interface, the second robot including a second top arm and a second bottom arm, the second top arm and second bottom arm substantially having a second range of motion which overlaps in part with the first range of motion.

Some embodiments provide a transfer system for use with a processing module, the transfer system including: a top arm and a bottom arm, the top arm and the bottom arm substantially having the same range of motion in substantially parallel planes; and a controller in communication with the top arm and the bottom arm programmed to: (a) move the top arm and bottom arm substantially together into the processing module; and (b) move the top arm and bottom arm out of the processing module with bottom arm leading.

Some embodiments provide a dual-robot transfer system for use with a supply-and-accept system and a processing module, said dual-robot processing system including: a first robot including a first top arm and a first bottom arm, the first top arm and the first bottom arm having substantially the same first range of motion in first substantially parallel planes; a second robot including a second top arm and a second bottom arm, the second top arm and the second bottom arm having substantially the same second range of motion in second substantially parallel planes, the first robot and second robot arranged so that first range of motion and second range of motion overlap; and a controller in communication with the first top arm, the first bottom arm, the second top arm, and the second bottom arm, programmed to: (a) move the first top arm and first bottom arm substantially together into the processing module with the first top arm carrying a first unprocessed work-piece; (b) move the second top arm and second bottom arm substantially together into the processing module with the second top arm carrying a second unprocessed work-piece; (c) move the first top arm and first bottom arm such that they leave the process module with the first bottom arm leading and carrying a first processed work-piece; and (d) move the second top arm and second bottom arm such that they leave the process module with the second bottom arm leading and carrying a second processed work-piece.

Some embodiments provide a method of transferring work-pieces to and from a processing module, the method including: transferring two un-processed work-pieces from the transfer module into the processing module using two top robot arms moving at substantially a same first time, during a first time period; and transferring two processed work-pieces from the process module into the transfer module using two bottom robot arms moving at substantially a same second time, during a second time period, the second time period starting after the first time period.

### BRIEF DESCRIPTION OF THE DRAWINGS

FIG. 1 is a diagram of wafer transfer system coupled to a process module.

FIG. 2 is a drawing of a photograph of a wafer transfer system including a transfer module with its lid closed.

FIG. 3 is a drawing of a photograph of the wafer transfer system of FIG. 2 with the lid of the transfer module open and with only one robot installed.

FIG. 3A is a drawing of a photograph of the robot of FIG. 3 with a cooling plate installed.

FIG. 3B is a drawing of a photograph of the cooling plate of FIG. 3A including raised pins for supporting work-pieces during cooling.

FIG. 4 is a drawing of a photograph of the back of the wafer transfer system of FIG. 2 without the process module installed.

FIG. 5 is a drawing of the transfer system and process module of FIG. 1 with dimensions marked in inches.

FIG. 6 illustrates methods performed by an interface, a transfer module, and a process module to accept unprocessed wafers and produce processed wafers.

FIGS. 7A-7T illustrate the system of FIG. 1 transferring wafers to and from a supply-and-accept module and process module.

### DETAILED DESCRIPTION

Some embodiments of the disclosed subject matter include work-piece transfer systems that can transfer work-pieces to and from various locations. Work-pieces can include, any object to be transferred by embodiments of the disclosed subject matter, for example, work pieces can include semiconductor materials (e.g., silicon wafers, gallium arsenide wafers, quartz wafers, silicon carbide wafers, etc.), biological samples (e.g., dishes containing biological experiments, etc.), etc. Some embodiments can provide high speed transfer of work-pieces while creating only a small foot print. Some embodiments include various robots having ranges of motion that overlap with the ranges of motions of others of the various robots and that are controlled so that neither the robots, nor the work-pieces, collide while transferring work-pieces from one location to another.

The described embodiment is a wafer transfer system that uses two two-armed robots, located substantially in a transfer module, to transfer wafers to and from an interface, the transfer module, and a processing module. The two arms of each robot rotate about one axis but operate independently. The described embodiment accepts unprocessed wafers from the interface, processes the wafers in the processing module, and provides the then processed wafers back to the interface.

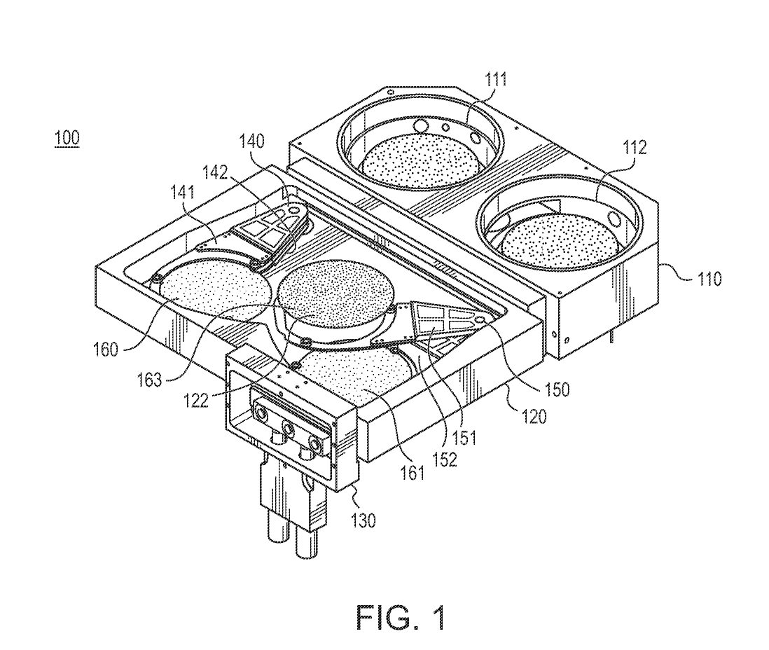

Referring to FIG. 1, the described embodiment is a wafer processing system 100 that includes a processing module 110, a transfer module 120, and an interface 130 to a wafer supply-and-accept system (not shown). Transfer module 120 includes left robot 140, with left upper arm 141 and left lower arm 142. Transfer module 120 also includes right robot 150, with right upper arm 151 and right lower arm 152. Each of arms 141, 142, 151, and 152 includes a C-shaped end effector for holding wafers. As shown, the end effector of left upper arm 141 holds nothing; the end effector of left lower arm 142 (hidden by left upper arm 141) holds processed wafer 160; the end effector of right lower arm 152 holds processed wafer 161; and right upper 151 arm is moving between buffer station 122 (in which unprocessed wafer 163 is currently sitting) and interface 130. Each robot arm can use high performance gear-sets that provide low/zero backlash, high torque, compact size, and high positional accuracy, such as, for example a harmonic drive.

Process module 110 includes two wafer processing stations, 111 and 112, which are shown with a wafer being processed in each station. Processing can include physical and/or chemical modifications to the wafers. For example, a film can be deposited onto the wafers by physical vapor deposition (PVD), chemical vapor deposition (CVD), atomic layer deposition (ALD), etc; material can be removed from the wafers, using, for example, photoresist ashing, plasma etching, ion beam milling, etc; the surface of wafers can be modified with, for example, ion implantation, thermal annealing, etc; etc. Process module 110 also includes heating plates positioned under the location that wafers sit in process module 110. Pins under the wafers can be used to support the wafers and raise and lower the wafers various distances away from the heating plates (e.g., wafer can be positioned closer to the heating to the plate to heat them faster).

The wafer supply-and-accept system is an equipment front end module (EFEM) that transports the wafers from, e.g., a cassette or pod that holds the wafers, to transfer module 120 through interface 130. The EFEM also provides a temporary storage location for the wafers to be processed. When ready, an EFEM robot removes an appropriate wafer to be processed from the storage location and moves it to the transfer module. The EFEM robot also removes processed wafers from the transfer module and returns them to the storage location.

The robot arms hold the wafers in their C-shaped end effectors using gravity and a fixed edge grip design with pads. In some embodiments, the end-effectors can include active edge grippers that push edges of the wafer against another edge or against a stopper. Active edge grip can be controlled by a vacuum.

All four of the robot arms can be positioned inside process module 110 at the same time. This permits an arm to transfer an unprocessed wafer into process module 110 at the same time that another arm retrieves a processed wafer from process module 110. The geometry of system 100 permits load motions (e.g., placing a wafer into process module 110) and unload motions (e.g., removing a wafer from process module 110) to overlap, thereby reducing wafer swap times. In addition, the dual robots, (e.g., left robot 140 and right robot 150) allow two processed and two unprocessed wafers to be handled at the same time, which further increases the wafer handling speed of system 100. Each end effector's path of motion overlaps with the path of motion of a corresponding end effector of an arm in the opposite robot. For example, the range of motion of left upper arm 141 overlaps with the range of motion of right upper arm 151. To avoid collisions between the arms, one pair of arms (e.g., the arms of left robot 140) is sequenced to follow the other pair of arms (e.g., the arms of right robot 150) into process module 110.

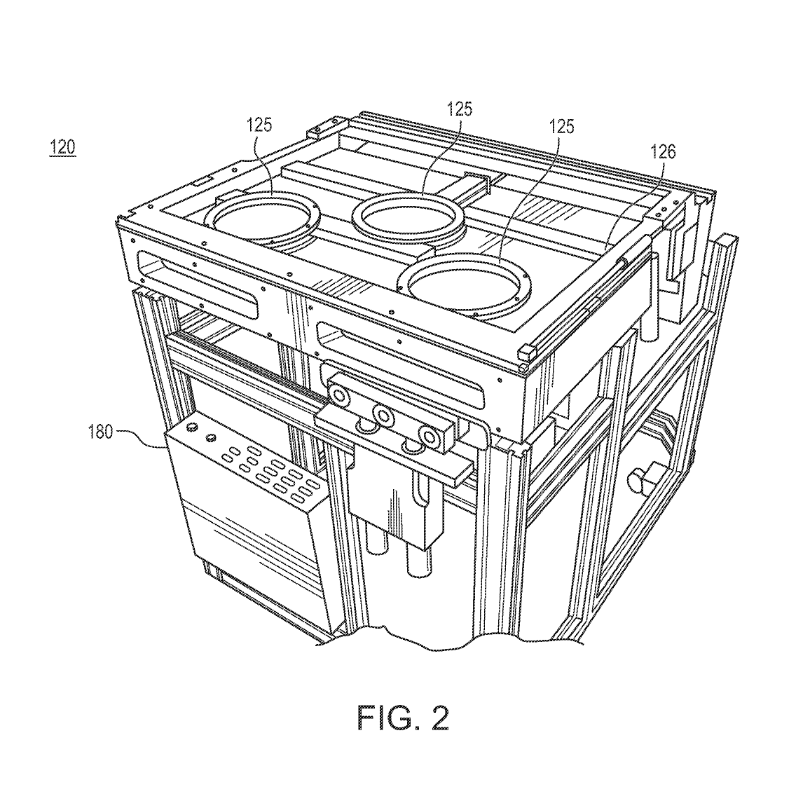

FIG. 2 is a drawing of a photograph of transfer module 120 with lid 126 closed. As shown, transfer module 120 includes three view-ports 125 through lid 126. Controller 180 is attached to the front of transfer module 120.

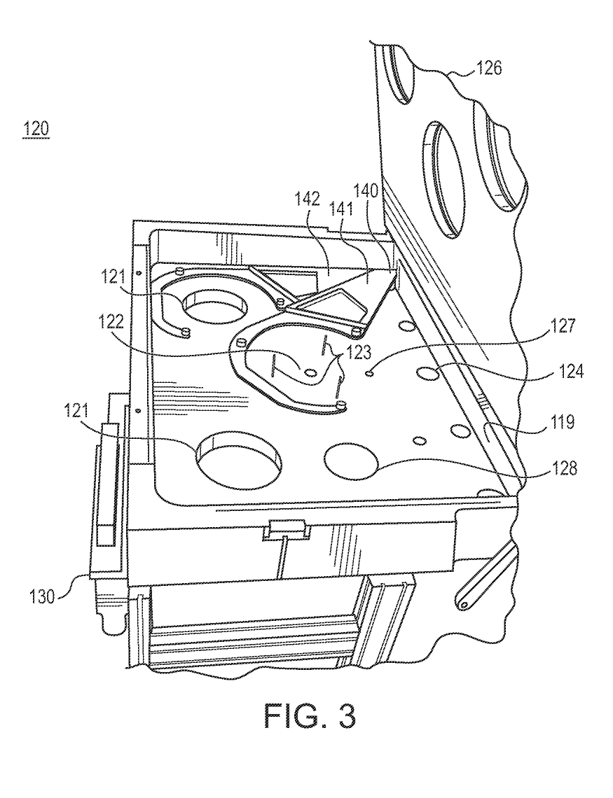

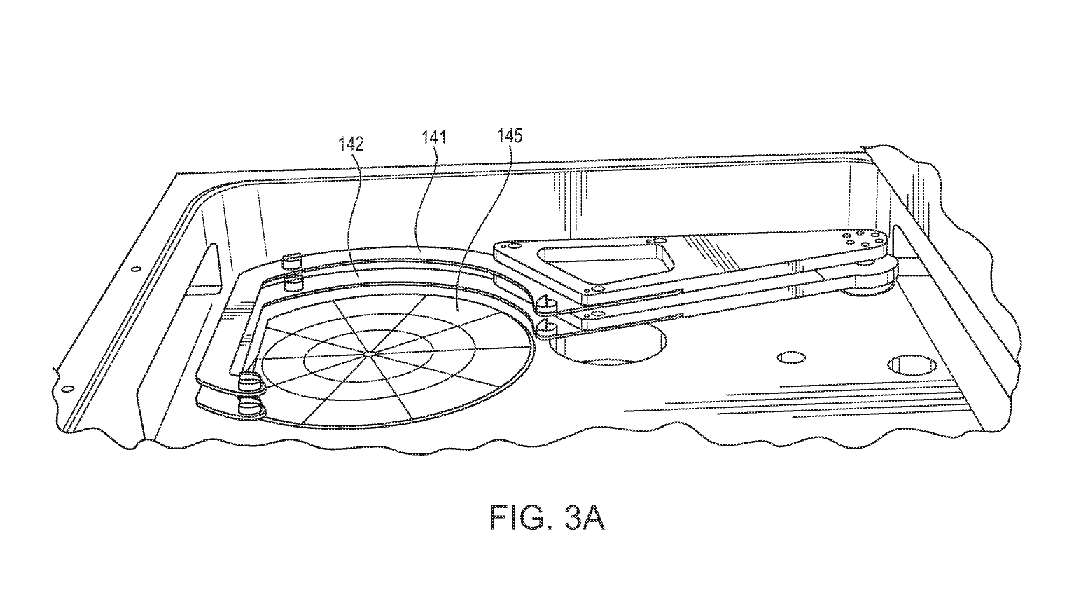

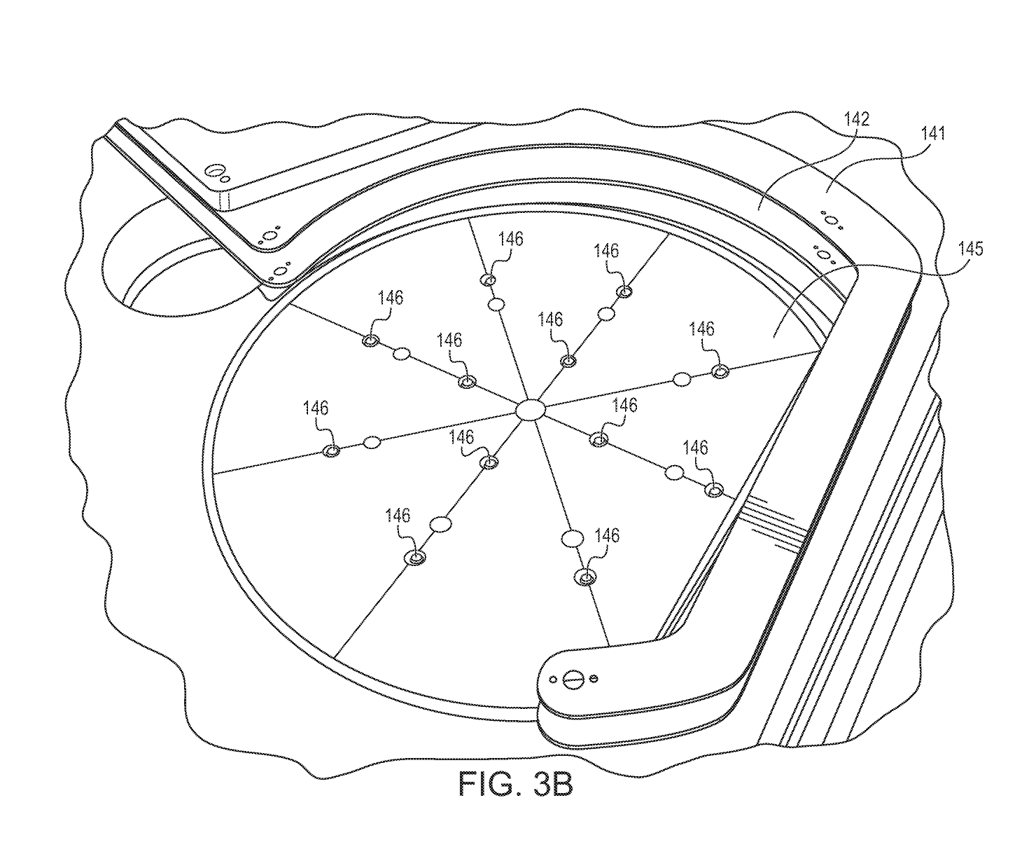

FIG. 3 is a drawing of a photograph of transfer module 120 with its lid open. Arms 141 and 142 of left robot 140 are visible, together with their “C”-shaped end effectors. Interface 130 is also visible. Right robot 150 is not installed. Buffer station 122 includes three lift pins 123 that are raised and lowered to load and unload a wafer from a robot arm picking or placing a wafer from buffer station 122. Transfer module 120 includes hole 127 where a sensor is installed that determines whether a robot arm passing over the sensor (and into or out of process module 110) is holding a wafer. Whether a wafer is expected to be in a robot arm depends on the function to be performed. For example, a wafer will be present at the start of a load cycle and empty at the end of the load cycle. If the wafer state (true/present or false/not-present) is not correct, the cycle is stopped. The sensor can be, for example, Banner sensor Mfr Part No. QS30LLP available from Banner Engineering Corp (www.bannerengineering.com). Hole 124 is used for venting as discussed in more detail below. Holes 121 are installed with shafts with cooling plates attached that can be raised and lowered to come into and out of contact with wafers being held by robot arms. The cooling plates can be raised and lowered using compressed air and stop based on a hard stop (e.g., due to coming into contact with a wafer).

FIG. 3A is a drawing of a photograph of robot 140 with a cooling plate 145 installed underneath it. FIG. 3B is a drawing of a photograph of the cooling plate of FIG. 3A installed with pins 146 that come into contact with wafers (instead of having the flat surface of the cooling plate contact wafers directly).

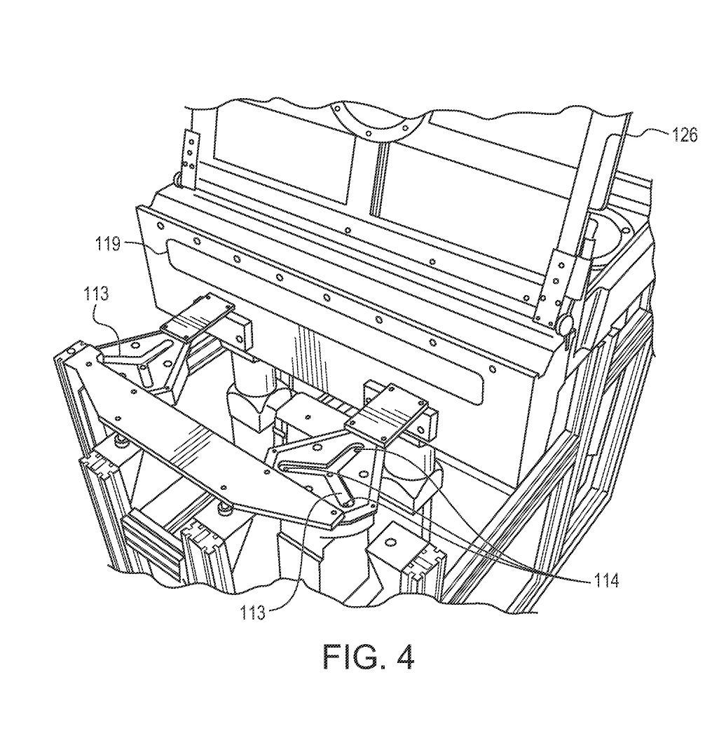

FIG. 4 is a drawing of a photograph of the back side of the wafer transfer system showing the location where process module 110 can be installed (i.e., process module 110 is not installed in FIG. 4). Lid 126 is open blocking view of most of the inside of transfer module 120. Processing module 110 includes wafer lift pins that raise and lower the wafers for picking off of and placing onto the end effectors of the robot arms when in process module 110. FIG. 4 shows lift pin assemblies for the process chamber with actual pins not installed. The lift pins can be installed in holes 114. The top surface of the lift pin assembly bolts to the bottom of process module 110. Each of the three lifts pins mount at each tip of the “Y” shaped piece (113) in the center of the assembly and extend up from the lift pin assembly, through the bottom of process module 110. The entire Y shaped pieces 113 can be located on the inside of seals that seal the process module from the environment.

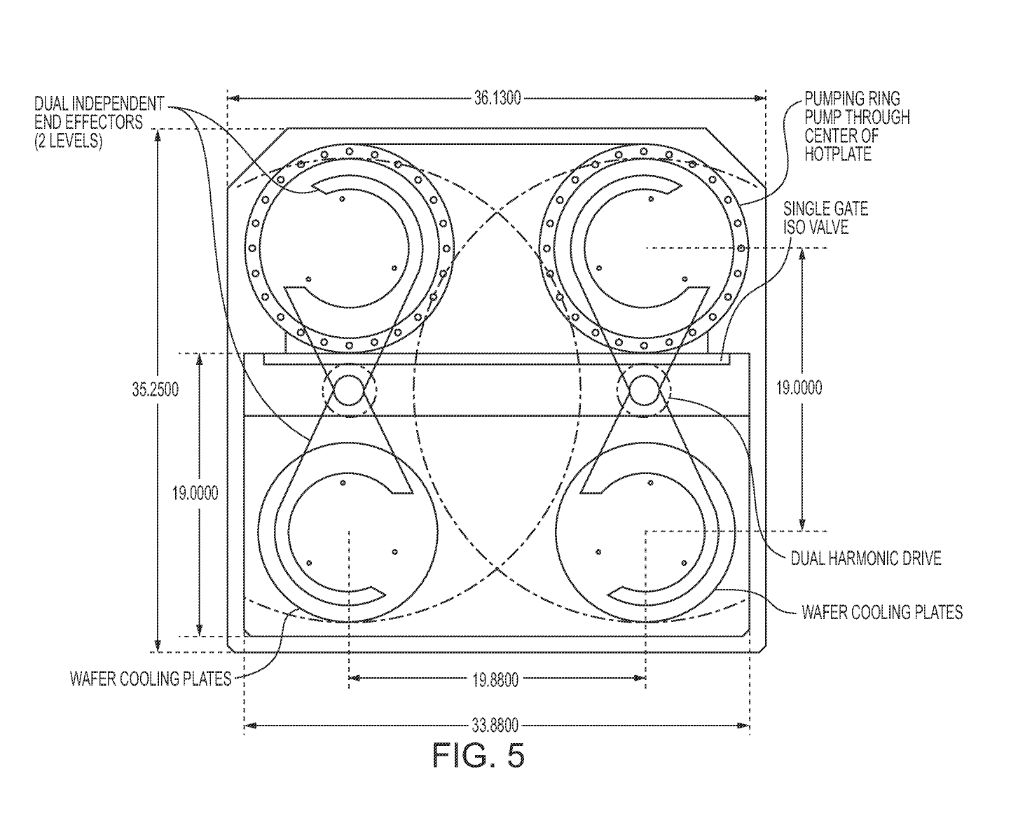

FIG. 5 is a drawing of the transfer module 100 with dimensions marked in inches. The dotted lines show the arcs shaped range of motion swept out by the robot arms as they transfer wafers between transfer module 120 in the lower half of the figure and the process chamber 110 in the upper half. As shown, the range of motions of robot 140 and robot 150 overlap and span approximately 180 arc degrees.

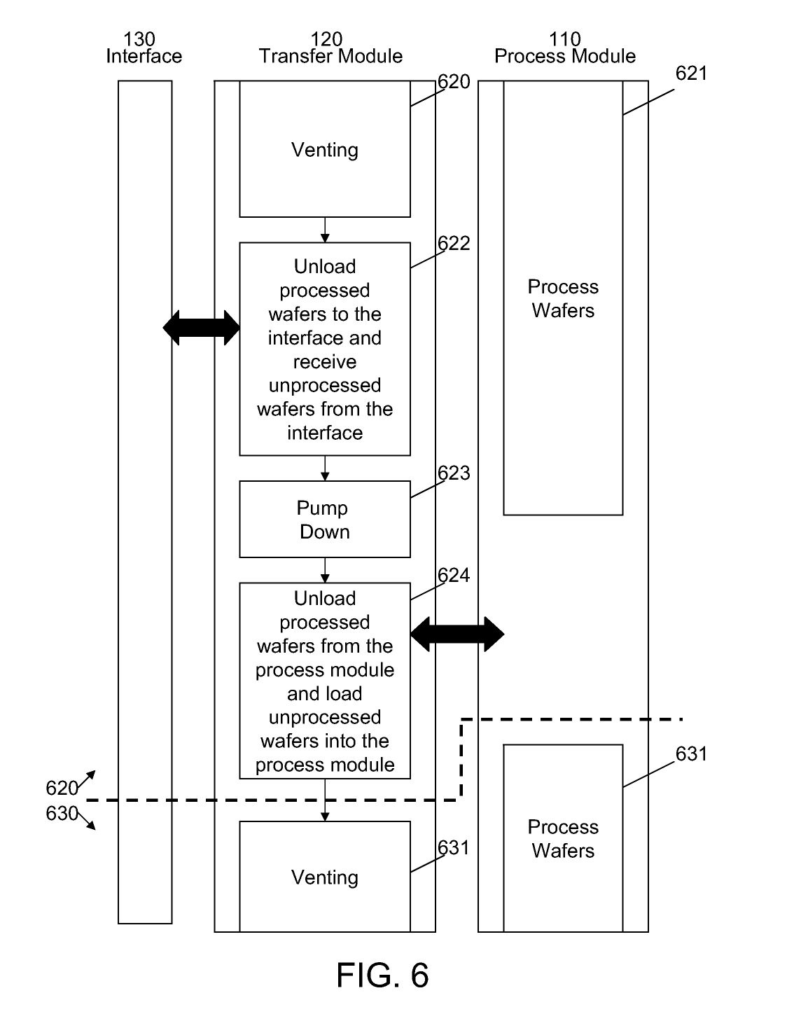

FIG. 6 is a flow chart showing a high level view of the steps performed by system 100 in a full wafer transfer cycle that transports two unprocessed wafers from interface 130 to process chamber 110 and two processed wafers out of process chamber 110 and to interface 130. At the start of this sequence, transfer module 120 is venting (at 620) with two already processed wafers inside it and process module 110 is processing (at 621) two currently unprocessed wafers. When transfer module 120 is done venting, the two processed wafers are exchanged (at 622) for two unprocessed wafers through the interface to the wafer supply-and-accept system. At 623, transfer module 120 is pumped down to base pressure. During or near the time that transfer module is pumping down, process module 110 finishes processing the wafers inside it. At 624, transfer module 120 removes the now processed wafers from process module 110 and loads process module 110 with unprocessed wafers. This ends wafer transfer cycle 620 and begins wafer transfer cycle 630. At about this time, transfer module 120 begins venting (at 631) and process module begins processing (at 632). That is, the process is now back at the same steps at which it started, but we are processing a new set of wafers in new cycle 630.

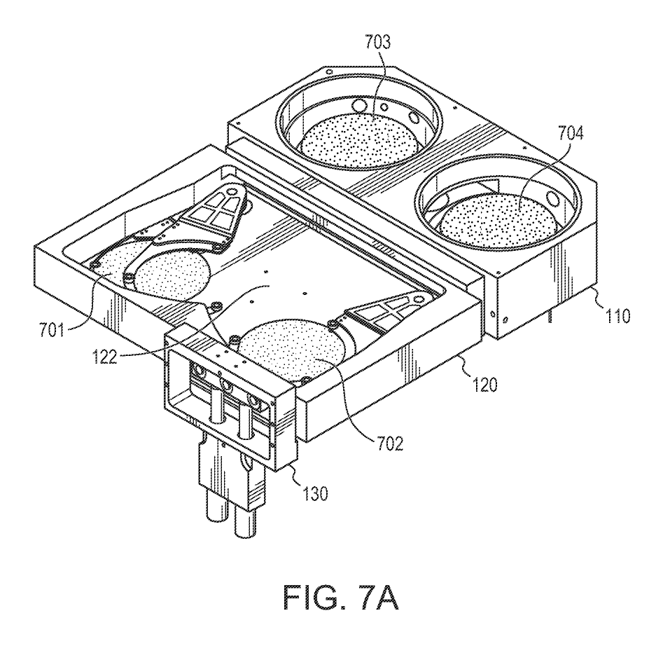

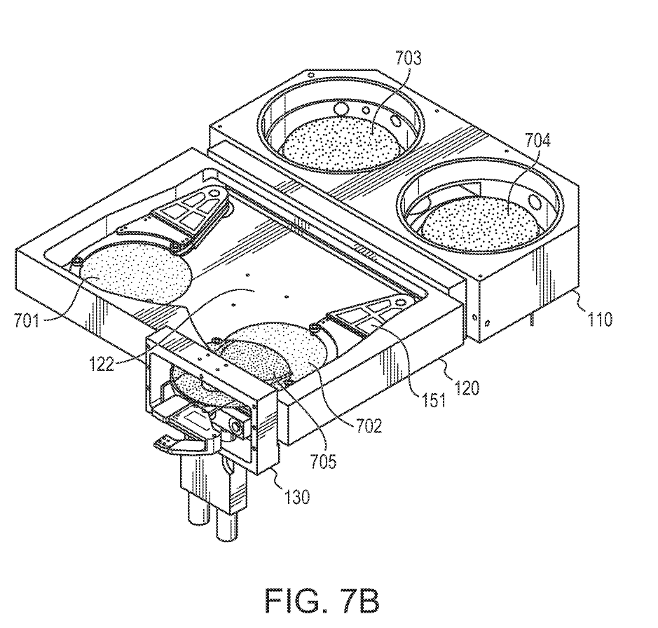

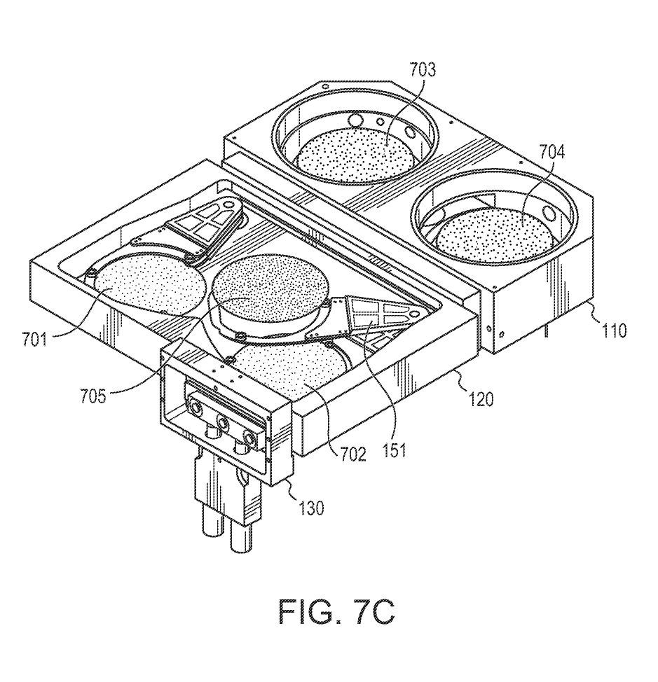

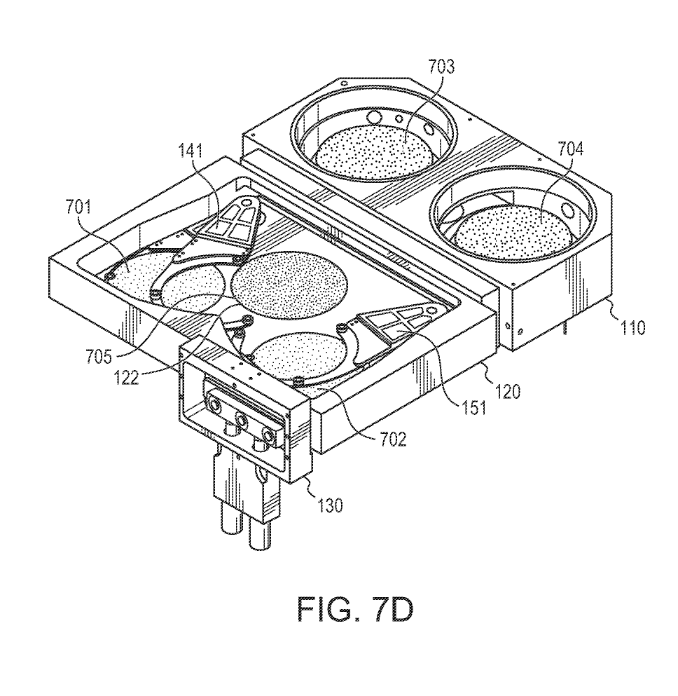

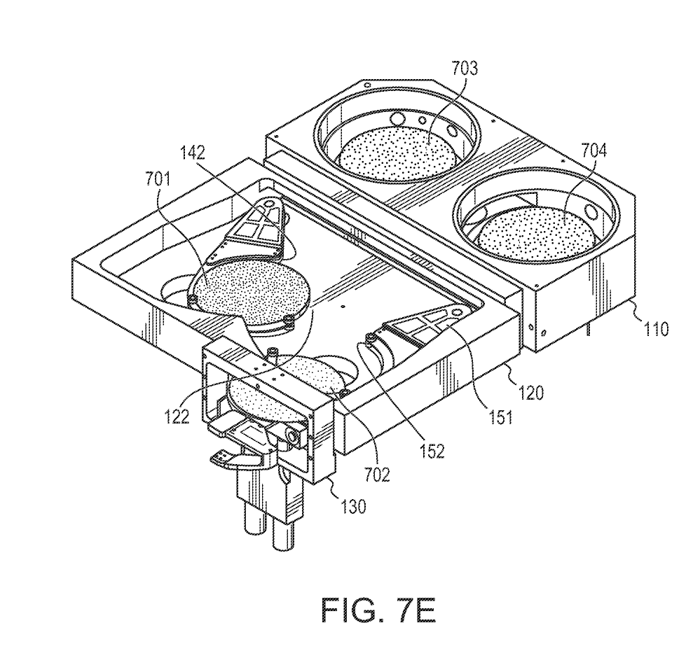

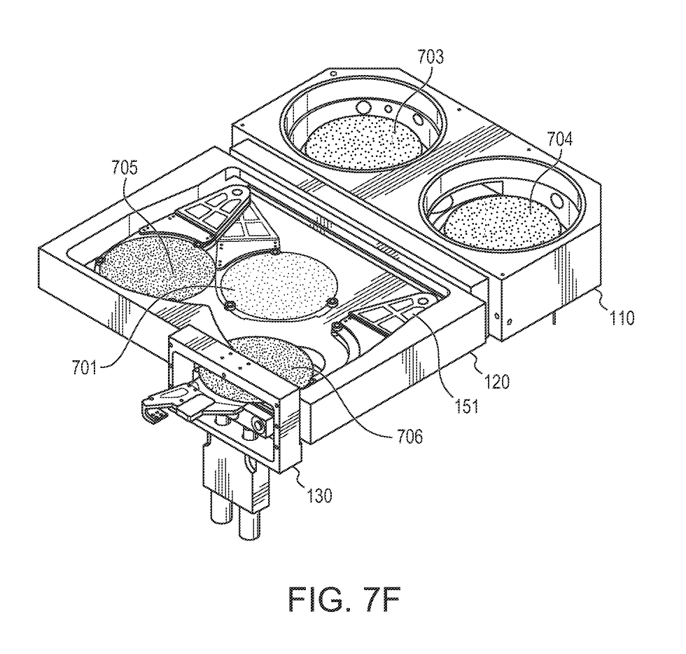

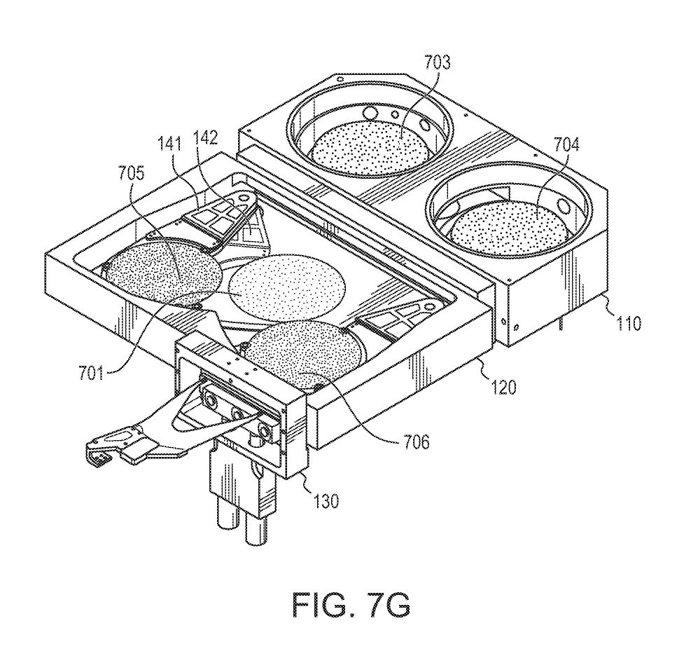

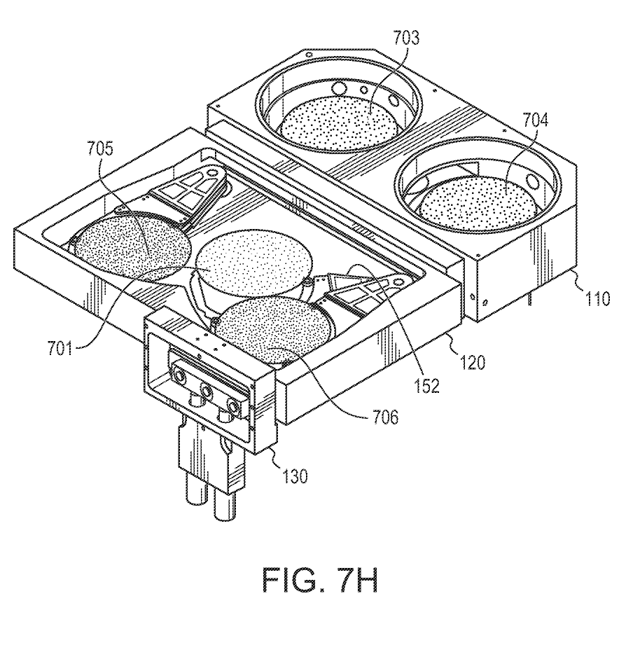

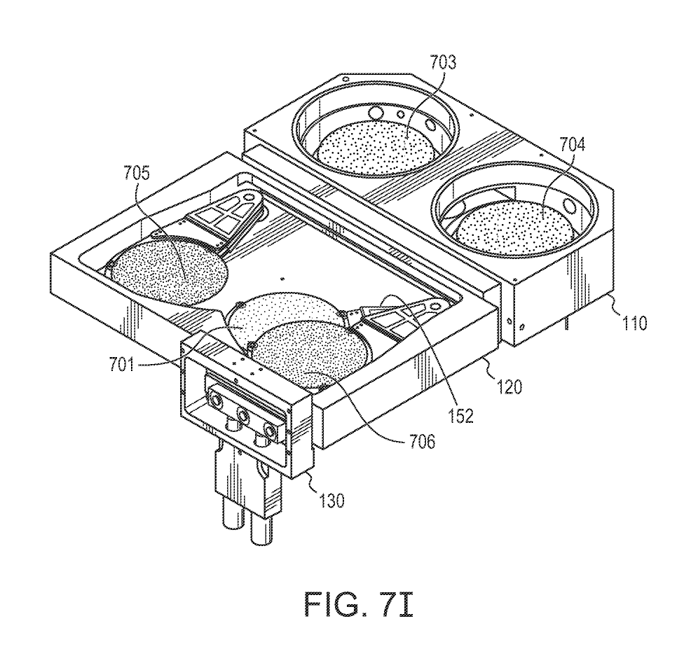

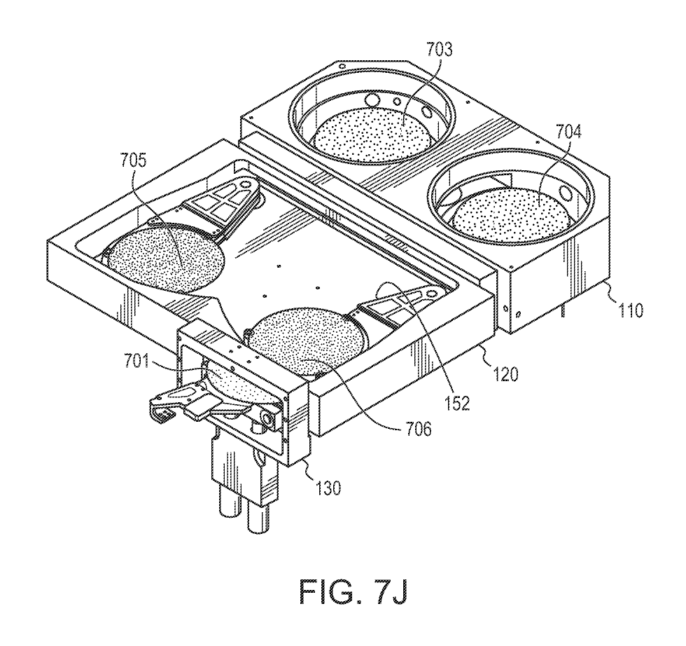

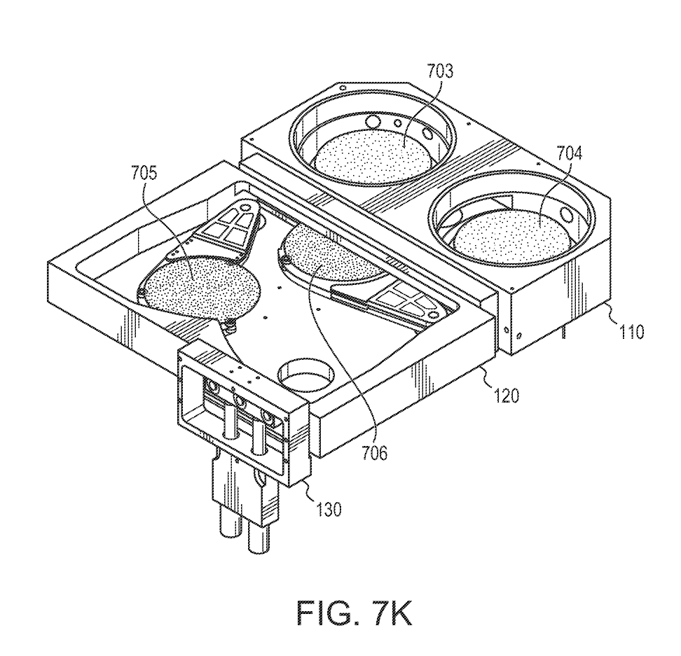

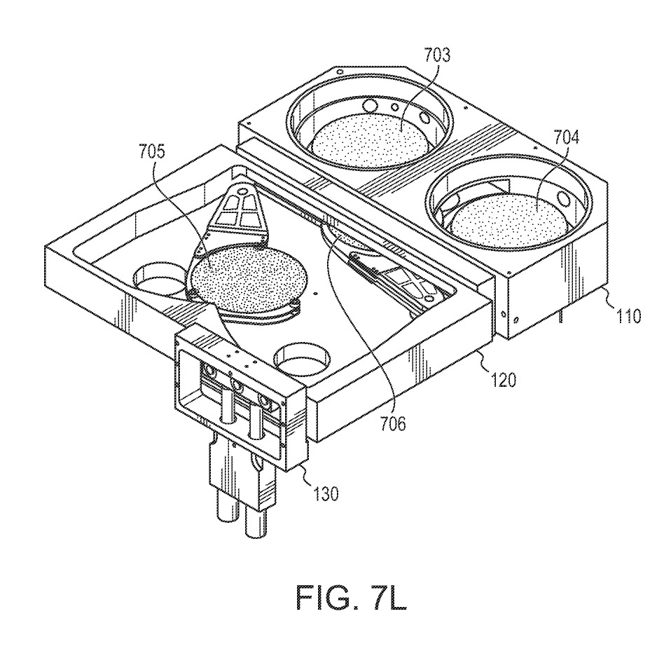

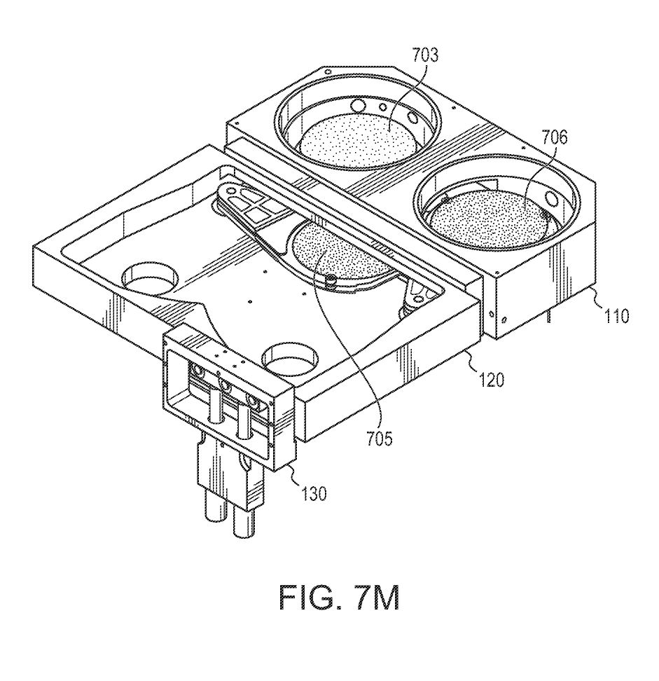

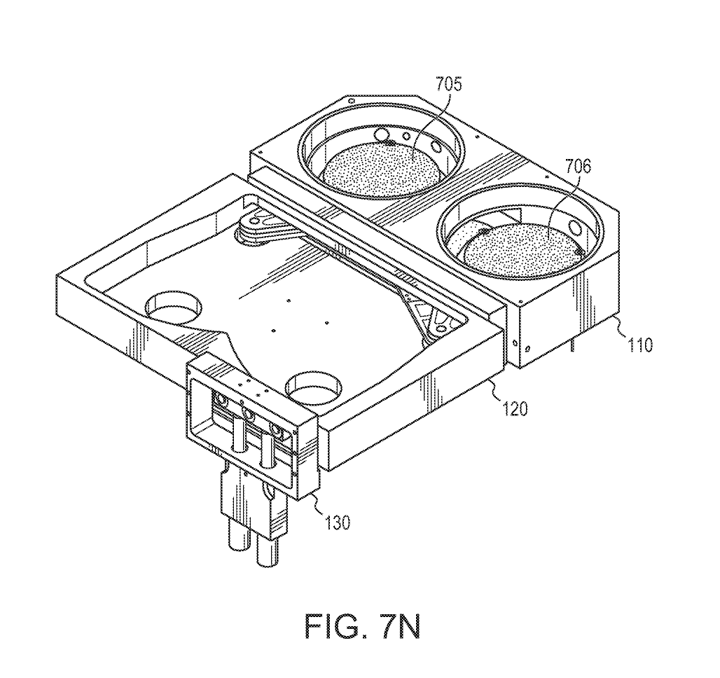

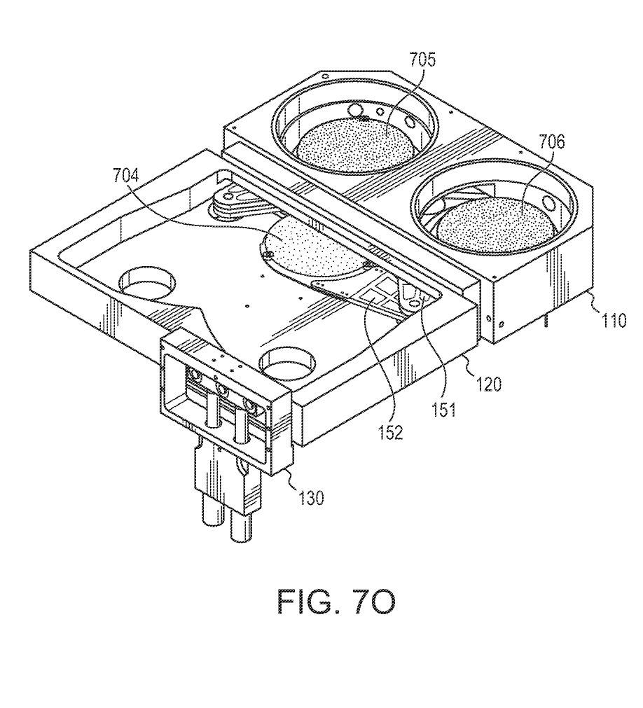

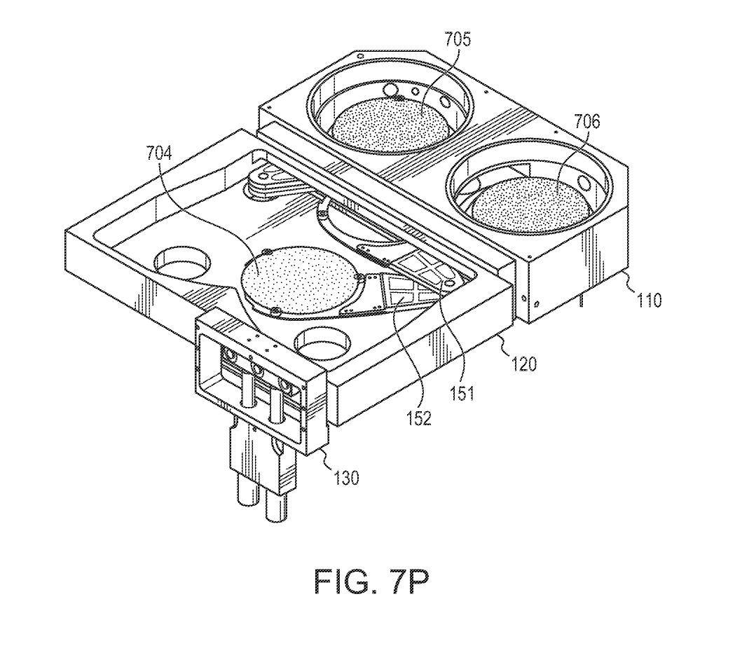

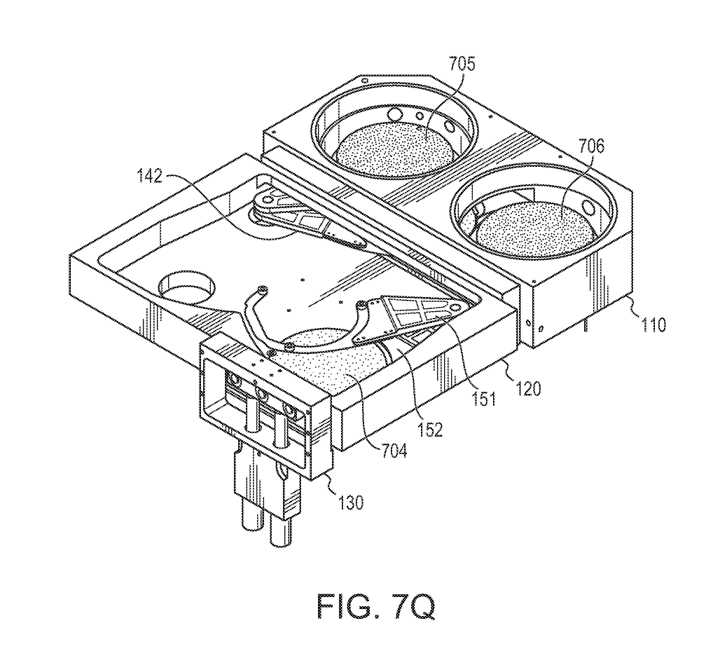

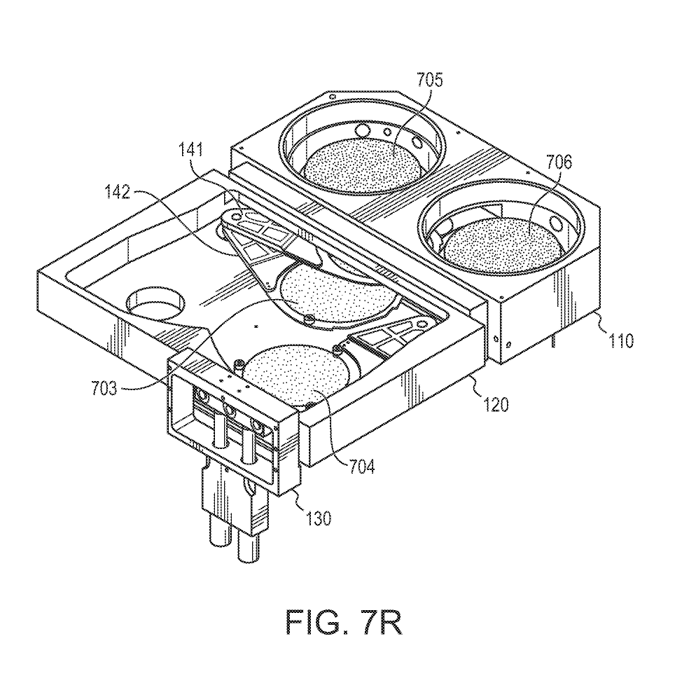

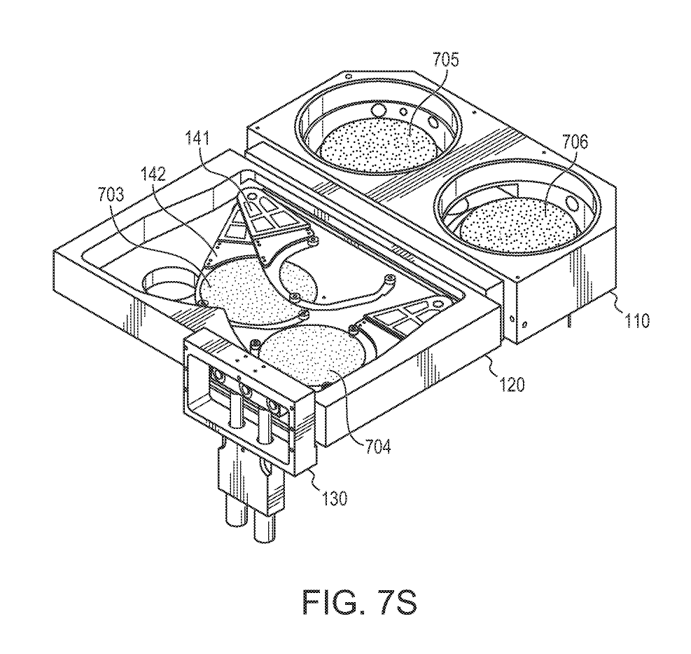

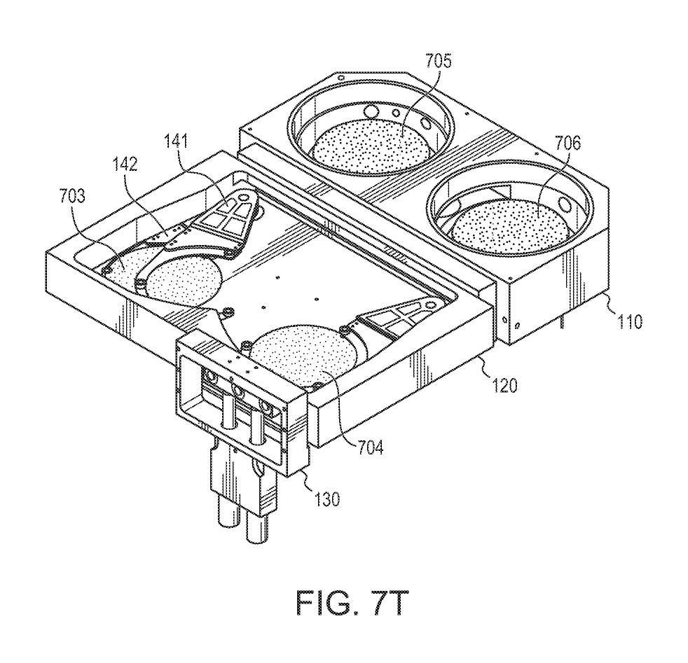

FIGS. 7A-7T illustrate the sequence of FIG. 7 in greater detail. At the start of this sequence, transfer module 120 is vented the lower robot arms each hold a processed wafer (i.e., wafers 701 and 702, which were processed in the previous cycle), processing module 110 is processing wafers 703 and 704, and the upper robot arms do not hold wafers. To start the sequence, the wafer supply-and-accept system selects two unprocessed wafers for processing (not shown). Transfer module 120 is vented using Nitrogen which is pressurized. When venting is required, vent valve opens which allows the pressurized nitrogen into the chamber (from hole 124 of FIG. 3). The valve is closed when the chamber reaches atmospheric pressure. The Nitrogen is at 80 PSI and is used to increase the pressure (the transfer chamber was at base pressure) until is reaches it atmospheric pressure. Pressure gauges are used to measure the air pressure and the valve is closed to the entry of Nitrogen when atmospheric pressure is reached.

As shown in FIG. 7B, the wafer supply-and-accept system then places an unprocessed wafer 705 on right upper arm 151. A shown in FIG. 7C, right upper arm 151 places unprocessed wafer 705 in buffer station 122 and then returns to interface 130. As shown in FIG. 7D, while right upper arm 151 is returning to interface 130 from buffer station 122, left upper arm 141 picks unprocessed wafer 705 from the buffer station and returns to its corner. While this is happening, as shown in FIG. 7E, the wafer supply-and-accept system accepts processed wafer 702 from right lower arm 152, and left lower arm 142 transfers processed wafer 701 to buffer station 122. As shown in FIGS. 7F and 7G, wafer supply-and-accept system places a second unprocessed wafer (wafer 706) onto right upper arm 151 and left lower arm 142 is returning to its corner after having placed processed wafer 701 in buffer station 122. As shown in FIGS. 7H and 7I, right lower arm 152 then picks processed wafer 701 from buffer station 122 and takes it to interface 130. As show in FIG. 7J, the wafer supply-and-accept system then picks processed wafer 701 from right lower arm 151. At this point in the sequence, processed wafers 701 and 702 are no longer in system 100 (because they have been accepted by the wafer supply-and-accept system), wafers 703 and 703 are still in processing module 110, and unprocessed wafers 705 and 706 are being held by the upper robot arms.

Transfer module 120 is then pumped down to a base pressure (through a seal connected to a vacuum located at hole 128 of FIG. 3), and vacuum door valve 119 (see FIGS. 3 and 4) that isolates process chamber 110 from transfer module 120 is opened. Various valves can be use, in the describe embodiment, the door valve of door 119 is made by VAT, Inc, model #02424-AA44-X (www.vatvalve.com). The valve is closed at all times except when the wafers are transferred in and out of the process module 110.

All four arms are rotated into the process chamber, with the right arms leading, and the left arms following (FIGS. 7K, 7L, and 7M). Once the arms are in process chamber 110, lift pins in process chamber 110 are lowered to place processed wafers 703 and 704 on the lower arms. The lower arms are retracted back into the transfer module chamber, with the right arm leading, while the lift pins in process chamber 110 pick the unprocessed wafers off the upper arms (FIGS. 7N, 7O). The upper arms are then retracted back into transfer module 120 with the right arms leading (FIGS. 7P, 7Q, 7R, 7S, 7T). Vacuum door valve 119 is closed, and wafer processing then starts in the process chamber on wafers 705 and 706. Transfer module 120 starts venting while cooling plates are raised to cool the processed wafers on the lower arms. When atmospheric pressure is reached in transfer module 120, the cooling plates are lowered, the vacuum door valve is opened, and the cycle is restarted. In the described embodiment, process module 110 is kept at a low pressure (typically not base pressure since the pressure changes during processing). The process chamber can be vented to atmospheric pressure for service reasons.

Each of the four robot arms is controlled independently by controller 180, a multi-axis servo controller, e.g., a DMC-40×0 motion controller from Galil Motion Control (www.galilmc.com). Controller 180 stores a program or programs that control motion of the robots and stores control parameters. Controller 180 receives high level commands, e.g., pick at process location, place at process location, go home, process lift pins up, process lift pins down, etc. from an external digital processing device (not shown) (e.g., a server computer running an off-the shelf operating system) that oversees operation of the system. The home location can be set using the software and movements of the robots can be based on/made relative to the home location. For example, the external digital processing device can instruct controller 180 to make left lower arm 142 “go home.” Controller 180 knows where “home” is (e.g., coordinates of a point near the left corner) and will move the robot to that “home” location. The external digital processing device also sends and receives commands to/from other digital processing device. The logic that controls the robot arms is software based and can be updated. Variables can be set/changed. These changes are made by an operator or by a host computer which is controlled by a fabrication manufacturing control system. Controller 180 also monitors the sensor located at 127 (FIG. 3). Controller 180 defines the motions of seven different components or groups of components: (1-4) each of the four robot arms; (5-6) raising and lowering two sets of lift pins in process module 110; and (7) raising and lowering the pins of buffer station 122. Controller 180 and/or the external digital processing device can include processors and computer-readable media storing computer-executable instructions that when executed by a processor cause the processor to perform the methods described herein, for example, those related to controlling motion of robots and transferring wafers.

The time taken for a single wafer transfer cycle (which produces two wafers) to complete is about thirty seconds. Thus, the wafer throughput rate of the described embodiment is about 240 wafers per hour (i.e., 2 wafers every 30 seconds=4 wafers per minute; 60 minutes times 4 wafers per minute=240 wafers). The cycle time includes about six second for pump down and eight seconds for venting. To pump the transfer chamber, a valve between the chamber and a vacuum pump is opened. The air in the chamber is pumped out until the chamber reaches base pressure. The pressure is measured by a gauge in the chamber. A typical total process time is about 28 seconds (i.e., the time from the closing of the process chamber slot valve to the open time). In the described embodiment the wafers can be up to 300 mm silicon wafers per the specification SEMI M1.15-1000, available from Semiconductor Equipment and Materials International (SEMI) at, for example, www.semi.org. The wafer transfer plane is 1100 mm per the specification SEMI STD E21-91. System 100 drops less than about 1 drop per 25,000 wafers transferred. Each wafer cooling plate has a capacity to cool about 100 wafers per hour. The cooling plates cool the wafers from an initial temperature of about 300° C. to about 60° C. in about 8 seconds during the venting phase of the cycle. The cooling plates can be raised and lowered to mate with the robot end effector for maximum wafer contact area. The pads on the C-shaped end effectors can be Ultem with Kalrez pads. The robot accuracy is about +/−about 0.01 degrees. The wafer placement accuracy is less than or equal to about 0.25 mm. The mean cycles between failure is at least about 1 million cycles. The mean time to repair (MTBR) is less than two hours. The base vacuum is about 5×10⁻⁴ Ton. The vacuum leak rate is less than about 1×10⁻⁸ std cc/sec He. The transfer chamber volume is less than about 25 liters maximum. Its width at the widest point is about 1000 mm. Regarding particle contamination, the mean add particles per wafer is <5 particles at >0.12 microns, <3 particles at 0.25 microns, <2 particles at >0.70 microns, 95% of data <10 total adders.

In various embodiments various robot arms can be in different planes. For example, robot arms 141, 142, 151, and 152 can: each be in a different plane and can move through their entire ranges of motion without colliding (even when holding wafers); each be in a different plane and can move through their entire ranges of motion without colliding (but, arms 141 and 151 may not move through their entire ranges of motion when holder wafers with out colliding with each other, and arms 142 and 152 may not move through their entire ranges of motion when holding wafers with out colliding with each other). When, for example, the robot arms move in different planes, sequences with which they can transfer work-pieces have more freedom.

In various embodiments, robot arms 141, 142, 151, and 152 can move using various sequences. For example, returning to FIG. 7N, where each of arms 141, 142, 151, and 152 are in process chamber 110. In some embodiments, lower arms 142 and 152 leave process module 110 prior to arms upper 141 and 151. If, for example, arms 142 and 152 are in different planes (and the planes are far enough away from each other that arms 142 and 152 can move above/below each other while holding wafers) arms 142 and 152 can leave process module 110 at the same time. Or, for example, if they are in different planes (but not far enough away from each other that arms 142 and 152 can move above/below each other while holding wafers) then arms 142 and 152 can leave process module 110 with one arm leading the other (e.g., arm 152 slightly leading) and can do so with arms 142 and 152 partially overlapping (e.g., part of the end effectors can overlap, but the arms may not overlap enough so that the wafers collide).

The following is a non-limiting list of example materials that can be used for various components of the system:

| | |
|---|---|
| End Effectors | Alumina (AL2O3), Silicon Carbide (SiC), |
| | Molybdenum and/or any suitable composite material |
| | such as AlSic |
| End Effector | Aluminum or Stainless Steel |
| Brackets (part of | |
| robot arms) | |
| Transfer and | Aluminum or Stainless Steel |
| process chambers | Transfer and process |
| including lids | |
| Arm pads | Aluminum, Alumina, Ceramic, Vespel ®, or |
| | Teflon ® |
| Cooling plates | Aluminum |
| Buffer station | Aluminum or Alumina |
| pins | |
| View port | Sapphire or quartz |
| windows | |
| Robot shafts | Stainless Steel |
| (connected to the | |
| end effector | |
| brackets) | |
| Seals | Perfluoronated Elastomer, Viton ®, and/or clear |
| | Silicon |

In various embodiments, various types of process modules, interfaces, and wafer or substrate supply-and-accept system can be used with transfer module 110. System 100 can include various numbers of robots, for example, a transfer module 110 can have four robots, be twice as wide, and be connected to a wider or to multiple process modules and/or interfaces. System 100 can also include only one robot, for example, only right robot 150. The various robot arms can operate on various planes, for example, they can each operate on a different plane. The circular shaped wafers sometimes referred to above can be substituted for various work-pieces of various shapes, such as, for example, octagonal, square, rectangular, and the various components of system 100 can be changed accordingly. The end effectors need not be C-shaped, and can be shaped, for example, depending on the shape of the work-piece being transferred. Shapes can include, for example, any shape with an open space on one side. Work-pieces can go through various processing steps, as such, the use of the words “processed” and “un-processed” are relative terms. For example, a work-piece about to go through process “X” can be referred to as unprocessed even though it was previously processed differently by a process “Y.” The arms of the robots arms can have various ranges of motions having various shapes. In some embodiments, various robot arms can transfer work-pieces directly between each other without, for example, using a buffer station. Processing can depend on the type of work-piece being processed and can include, for example, applying or adding a substance, heating, cooling, incubating, mixing, shaking, spinning, removing part of the work-piece, etc. A controller, e.g., controller 180, can be, for example, the only controller, can be part of a larger controller, can be controlled by or work in conjunction with an external controller, or can be absent entirely and the system can be controlled by an external controller. The measurements in FIG. 5 are merely examples, both, for example, the measurements themselves and the relationships between different measurements can be altered. Cooling plates and/or pins on the cooling plates can be installed (or not installed) and/or used or not used, in various embodiments, depending on, for example, the type of work-piece piece used and/or the tolerance of work-pieces to changes in temperature. For example, pins can be used in embodiments where having the body of a cooling plate come into direct contact with the work-piece could damage the work-piece.

Although the invention has been described and illustrated in the foregoing illustrative embodiments, it is understood that the present disclosure has been made only by way of example, and that numerous changes in the details of implementation of the invention can be made without departing from the spirit and scope of the invention, which is limited only by the claims that follow. Features of the disclosed embodiments can be combined and rearranged in various ways within the scope and spirit of the invention.

What is claimed is:

1. A dual-robot transfer system for use with a supply-and-accept system and a processing module, said dual-robot transfer system comprising:
a transfer module for transferring work-pieces into and out of the process module;
a physical interface between the transfer module and the supply-and-accept system which supplies unprocessed work-pieces to the transfer module and accepts processed work-pieces from the transfer module;
a first robot located substantially in the transfer module for transferring work-pieces to and from the process module and a buffer station located in the transfer module, the first robot comprising a first top arm and a first bottom arm, the first top arm and first bottom arm substantially having a first range of motion; and
a second robot located substantially in the transfer module for transferring work-pieces to and from the process module, the buffer station, and the physical interface, the second robot comprising a second top arm and a second bottom arm, the second top arm and second bottom arm substantially having a second range of motion which overlaps in part with the first range of motion.

2. The dual-robot transfer system of claim 1, wherein the first top arm and second top arm move within a same first plane and the first bottom arm and second bottom arm move within a different same second plane.

3. The dual-robot transfer system of claim 1, wherein the first top arm, first bottom arm, second top arm, and second bottom arm each move within different planes.

4. The dual-robot transfer system of claim 1, wherein the first top arm and second top arm move within a same first plane, the first bottom arm moves within a different second plane, and the second bottom arm moves within a different third plane.

5. The dual-robot transfer system of claim 1, the buffer station comprising a plurality of pins arranged to raise and lower any work-piece placed thereon, the plurality of pins being located in an area where the first range of motion and the second range of motion overlap.

6. The dual-robot work-piece transfer system of claim 1, wherein the first range of motion and the second range of motion each: is substantially arc shaped, spans approximately 180 arc degrees, has one extreme located in the process module, has another extreme located in the transfer module, and rotates about a point located in the transfer module.

7. The dual-robot transfer system of claim 6, wherein the transfer module is substantially rectangular having four internal corners with a first two of the four corners substantially equidistant from the process module and closer to the process module than a second two of the four corners and wherein the point about which the first range of motion rotates is substantially located in a first of the first two corners and the point about which the second range of motion rotates is substantially located in a second of the first two corners.

8. The dual-robot transfer system of claim 1, each of the first top arm, first bottom arm, second top arm, and second bottom arm comprising a c-shaped end effecter for holding wafers.

9. The dual-robot transfer system of claim 1, further comprising a controller coupled to the transfer module comprising a processor and a computer-readable medium storing computer-executable instructions that when executed by the processor cause the processor to control the first and second robots including their transferring of work-pieces.

10. The dual-robot transfer system of claim 1, wherein the work-pieces comprise silicon wafers.

11. The dual-robot transfer system of claim 1, wherein the work-pieces comprise at least one of semiconductor materials and biological samples.

12. The dual-robot transfer system of claim 1, wherein the transfer module has an internal air pressure and further comprising:
controllable seals arranged to seal the transfer module from external air;
controllable vents arranged to vent the transfer module until its internal air pressure reaches approximately atmospheric pressure;
at least one air pressure gauge that measures the internal air pressure; and
an air interface coupled to a pump that decreases the internal air pressure until it reaches a base pressure.

13. The dual-robot transfer system of claim 1, wherein the process module performs at least one of: physical vapor deposition, chemical vapor deposition, atomic layer deposition, photoresist ashing, plasma etching, ion beam milling, ion implantation, thermal annealing, heating, cooling, mixing, shaking, and stirring.

14. The dual-robot transfer system of claim 1, further comprising a first cooling plate arranged to cool any wafer being held by the first bottom robot arm and a second cooling plate arranged to cool any wafer being held by the second bottom robot arm.

15. The dual-robot transfer system of claim 14, the first cooling plate and second cooling plate each comprising a top surface including pins arranged to prevent wafers from coming into direct contact with parts of the top surface other than the pins.

16. A transfer system for use with a processing module, the transfer system comprising:
a top arm and a bottom arm, the top arm and the bottom arm substantially having the same range of motion in substantially parallel planes; and
a controller in communication with the top arm and the bottom arm programmed to:
(a) move the top arm and bottom arm substantially together into the processing module; and
(b) move the top arm and bottom arm out of the processing module with bottom arm leading.

17. The transfer system of claim 16, wherein the range of motion is substantially arc shaped and spans approximately 180 arc degrees.

18. The transfer system of claim 16, the controller further programmed to remove a processed work-piece from the process module with the bottom arm and deposit an un-processed work-piece into the process module with the top arm.

19. A dual-robot transfer system for use with a supply-and-accept system and a processing module, said dual-robot processing system comprising:
a first robot comprising a first top arm and a first bottom arm, the first top arm and the first bottom arm having substantially the same first range of motion in first substantially parallel planes;
a second robot comprising a second top arm and a second bottom arm, the second top arm and the second bottom arm having substantially the same second range of motion in second substantially parallel planes, the first robot and second robot arranged so that first range of motion and second range of motion overlap; and
a controller in communication with the first top arm, the first bottom arm, the second top arm, and the second bottom arm, programmed to:
(a) move the first top arm and first bottom arm substantially together into the processing module with the first top arm carrying a first unprocessed work-piece;
(b) move the second top arm and second bottom arm substantially together into the processing module with the second top arm carrying a second unprocessed work-piece;
(c) move the first top arm and first bottom arm such that they leave the process module with the first bottom arm leading and carrying a first processed work-piece; and
(d) move the second top arm and second bottom arm such that they leave the process module with the second bottom arm leading and carrying a second processed work-piece.

20. The dual-robot transfer system of claim 19, wherein the first top arm, the first bottom arm, the second top arm, and the second bottom arm each move in different substantially parallel planes; and (a) and (b) occur at substantially the same time.

21. The dual-robot transfer system of claim 19, wherein the moving of the first bottom arm of (c) and the moving of the second bottom arm of (d) occur at substantially the same time and occur before the moving of the first top arm of (c) and the moving of the second top arm of (d).

22. The dual-robot transfer system of claim 19, wherein the first range of motion and the second range of motion each: is substantially arc shaped and spans approximately 180 arc degrees.

23. A method of transferring work-pieces to and from a processing module, the method comprising:
transferring two un-processed work-pieces from a transfer module into the processing module using two top robot arms moving at substantially a same first time, during a first time period; and
transferring two processed work-pieces from the process module into the transfer module using two bottom robot arms moving at substantially a same second time, during a second time period, the second time period starting after the first time period.

24. The method of claim 23, wherein the first time period and second time period overlap.

25. The method of claim 23, wherein each of the two top arms and two bottom arms move in different parallel planes and have ranges of motion that overlap with each other.
